(19) United States
(12) Patent Application Publication
(10) Pub. No.: US 2025/0204016 A1
(43) Pub. Date: Jun. 19, 2025

(54) Electronic Cascode Power Device

(71) Applicant: The Hong Kong University of Science and Technology, Hong Kong (CN)

(72) Inventors: Jing CHEN, Hong Kong (CN); Ji SHU, Hong Kong (CN)

(21) Appl. No.: 18/974,812

(22) Filed: Dec. 10, 2024

Related U.S. Application Data
(60) Provisional application No. 63/610,422, filed on Dec. 15, 2023.

(51) Int. Cl. H10D 80/20; H10D 8/25; H10D 30/47; H10D 62/824; H10D 62/85

(52) U.S. Cl. CPC H10D 80/251; H10D 8/25; H10D 30/471; H10D 62/824; H10D 62/8503; H10D 80/231

(57) ABSTRACT

The invention provides an electronic cascode power device. The electronic cascode power device has a high-side terminal, a low-side terminal and a control terminal. The electronic cascode power device comprises: a high-voltage silicon (Si) super-junction MOSFET with a drain connected to the high-side terminal of the cascode device; a low-voltage gallium nitride (GaN) HEMT with a drain connected to a source of the high-voltage Si super-junction MOSFET, a source connected to the low-side terminal of the cascode device and a gate connected to the control terminal of the cascode device; and an overvoltage clamping circuit connected between the drain and source of the low-voltage GaN HEMT. The provided cascode structure can effectively suppress the reverse-recovery process of super-junction MOSFET, achieving nearly 50% reduction in overall switching loss at high current levels.

### CROSS-REFERENCE TO RELATED APPLICATIONS

The present application claims priority from the U.S. Provisional Patent Application No. 63/610,422 filed on 15 Dec. 2023, and the disclosure of which is incorporated herein by reference in its entirety.

### FIELD OF THE INVENTION

The invention is generally related to power electronic devices, specifically related to an electronic cascode power device based on silicon (Si) super-junction (SJ) metal-oxide-semiconductor field-effect transistor (MOSFET).

### BACKGROUND OF THE INVENTION

High-voltage (HV) Si SJ-MOSFETs are widely used in power electronics applications, including the power supply of computers, air conditioners, and refrigerators. However, the pn-junction body diode of HV Si SJ-MOSFETs, when being turned on for reverse conduction, will result in a reverse-recovery process that exacerbates the switching loss.

The reverse-recovery effect can be alleviated by preventing the reverse conduction of HV Si SJ-MOSFET with a series-connected low voltage (LV) field-effect transistor (FET) or diode while providing a substitutional reverse-conduction path with an antiparallel-connected reverse-recovery-free high-voltage diode, such as a SiC Schottky-barrier diode (SBD). However, the HV SBD adds considerable output capacitance and thus compromises the reduction of switching loss.

Another solution is to divert the burden of reverse conduction and reverse recovery to an LV Si MOSFET by forming a cascode configuration. The shorter drift region of the LV Si MOSFET leads to a smaller amount of reverse-recovery charge (Qr). However, such reverse-recovery charge still cannot be fully eliminated due to the same pn-junction-based reverse-recovery process.

### SUMMARY OF THE INVENTION

One objective of the present invention is to substantially suppress the reverse-recovery process of an Si SJ-MOSFET so that the switching loss can be significantly reduced.

According to one aspect of the present invention, an electronic cascode power device is provided. The electronic cascode power device has a high-side terminal, a low-side terminal and a control terminal. The electronic cascode power device comprises: a high-voltage silicon (Si) super-junction MOSFET with a drain connected to the high-side terminal of the cascode device; a low-voltage gallium nitride (GaN) HEMT with a drain connected to a source of the high-voltage Si super-junction MOSFET, a source connected to the low-side terminal of the cascode device and a gate connected to the control terminal of the cascode device; and an overvoltage clamping circuit connected between the drain and source of the low-voltage GaN HEMT.

The cascode GaN/Si-SJ provided by the present invention successfully leverages the unipolar characteristics of GaN HEMTs which comprising no PN junction in the current path and exhibiting zero Qᵣᵣ after reverse conduction, therefore can substantially suppress the reverse recovery of HV Si SJ-MOSFET and decrease the switching loss significantly.

Thanks to the absence of Qᵣᵣ in the GaN HEMT, the cascode structure can effectively suppress the reverse-recovery process of SJ-MOSFET. The Qᵣᵣ of a 650-V/33-A Si SJ-MOSFET is decreased from 0.97 μC to only 0.02 μC at a reverse-conduction current of 30 A, leading to nearly 50% reduction in overall switching loss at high current levels, as verified by experiment results.

### BRIEF DESCRIPTION OF THE DRAWINGS

Embodiments of the invention are described in more details hereinafter with reference to the drawings, in which:

FIG. 1A shows a circuit schematic of an electronic cascode power device in accordance with one embodiment of the present invention; FIGS. 1B and 1C shows alternative embodiments of the waveform clipping circuit in FIG. 1A.

FIGS. 2A-2C show the reverse-conduction characteristics of the LV GaN HEMT, HV Si SJ-MOSFET, and the GaN/Si-SJ cascode device, respectively; and FIG. 2D shows the reverse-conduction current path in the GaN/Si-SJ cascode device;

FIGS. 3A and 3B shows the test set-ups used to characterize the device's reverse-recovery performance and the switching performance, respectively;

FIGS. 4A and 4B plot the voltage and current waveforms during the reverse-recovery process of the best-in-class Si FR-SJ-MOSFET at different reverse-conduction currents (I_{RC});

FIGS. 5A and 5B plot the voltage and current waveforms during the reverse-recovery process of the GaN/Si-SJ cascode device at different I_{RC};

FIG. 6 plots the switching process of the GaN/Si-SJ cascode device and the FR-SJ-MOSFET; and

FIG. 7 compares the switching loss of the FR-SJ-MOSFET and the GaN/Si-SJ cascode device.

### DETAILED DESCRIPTION

In the following description, details of the present invention are set forth as preferred embodiments. It will be apparent to those skilled in the art that modifications, including additions and/or substitutions may be made without departing from the scope and spirit of the invention. Specific details may be omitted so as not to obscure the invention; however, the disclosure is written to enable one skilled in the art to practice the teachings herein without undue experimentation.

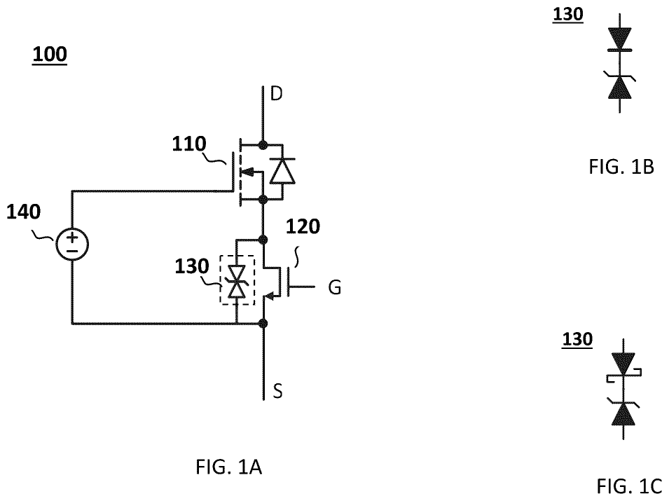

FIG. 1A shows a circuit schematic of an electronic cascode power device in accordance with one embodiment of the present invention. As shown, the electronic cascode power device 100 comprises an HV Si SJ-MOSFET 110, a LV GaN HEMT 120, an overvoltage clamping circuit 130. The electronic cascode power device 100 may have a device drain (or high-side terminal) D, a device source (or low-side terminal) S and a device gate (or control terminal) G.

The HV Si SJ-MOSFET 110 is configured to have its drain connected to the device drain D. The LV GaN HEMT 120 is configured to have its drain connected to a source of the high-voltage Si super-junction MOSFET 110, its source connected to the device source S and its gate connected to the device gate G. The overvoltage clamping circuit 130 may be connected between the drain and source of the LV GaN HEMT 120.

In some embodiments, the HV Si SJ-MOSFET 110 may be a normally-off MOSFET and the LV GaN HEMT 120 may be a normally-off GaN HEMT; and the device 100 further comprises a voltage source 140.

The voltage source 140 provides a constant voltage with reference to a source of the LV GaN HEMT 120 and having a value sufficient for turning on the HV Si SJ-MOSFET 110. For example, the voltage of the external voltage source 140 may be set in a range of 10 V˜15 V, which is sufficient for most of the commercial HV Si SJ-MOSFETs.

In some embodiments, the external voltage source 140 may include a capacitor connected between the gate of the HV Si SJ-MOSFET 110 and the source of the LV GaN HEMT 120, and configured for storing charges supplied from a driver system to maintain the constant voltage for turning on the HV Si SJ-MOSFET 110.

In some embodiments, the HV Si SJ-MOSFET 110 may be a normally-on MOSFET and the LV GaN HEMT 120 may be a normally-off GaN HEMT so that there is no need to implement a voltage source.

In some embodiments, the overvoltage clamping circuit 130 may include a pair of Zener diodes connected in series and opposite to each other. More specifically, circuit 130 may include a first Zener diode having an anode connected to the drain of the LV GaN HEMT; and a second Zener diode having a cathode connected to a cathode of the first Zener diode and an anode connected to the source of the LV GaN HEMT.

In some embodiments, the pair of Zener diodes may be replaced with a pn diode and a Zener diode connected in series and opposite to each other as shown in FIG. 1B. In other words, the overvoltage clamping circuit 130 may include a pn diode having an anode connected to the drain of the LV GaN HEMT; and a Zener diode having a cathode connected to a cathode of the pn diode and an anode connected to the source of the LV GaN HEMT.

In some embodiments, the pair of Zener diodes may be replaced with a Schottky barrier diode and a Zener diode connected in series and opposite to each other as shown in FIG. 1C. In other words, the overvoltage clamping circuit 130 may include Schottky barrier diode having an anode connected to the drain of the LV GaN HEMT; and a Zener diode having a cathode connected to a cathode of the Schottky barrier diode and an anode connected to the source of the LV GaN HEMT.

In some embodiments, the electronic cascode power device may have a dual die configuration including the HV Si SJ-MOSFET 110 and the LV GaN HEMT 120.

In some embodiments, the Zener diode 130 may be a separate device. In some embodiments, the Zener diode 130 can in practice be integrated with the circuit of the LV GaN HEMT 120.

In one exemplary implementation of the cascode GaN/Si-SJ structure, the SJ-MOSFET is a 650-V/33-A Si SJ-MOSFET, having its gate fixed to a 10-V rail. The LV GaN HEMT is a 40-V/3.2-mΩ GaN HEMT having its gate being the control gate. The GaN HEMT is connected in parallel with a 17-V Si bi-directional Zener diode to protect the Si SJ-MOSFET's gate from negative overstress during the switching process.

Since the lateral LV GaN HEMT exhibits a much smaller gate charge Q_{G} (e.g., 8.7 nC) than the HV Si SJ-MOSFET (e.g., 72.5 nC), the switching speed of the cascode GaN/Si-SJ device can be faster with lower loss. The 10-V rail can be co-designed into the gate driver circuit of the LV GaN HEMT as they share the same ground. Thus, the simplicity of the driver circuit is not compromised significantly.

During the reverse-conduction process, the Si SJ-MOSFET is in ON state since its gate-source voltage is 10 V. As a result, the reverse-conduction current flows through the Si SJ-MOSFET mainly via the ON-state MOS channel instead of the pn-junction body diode.

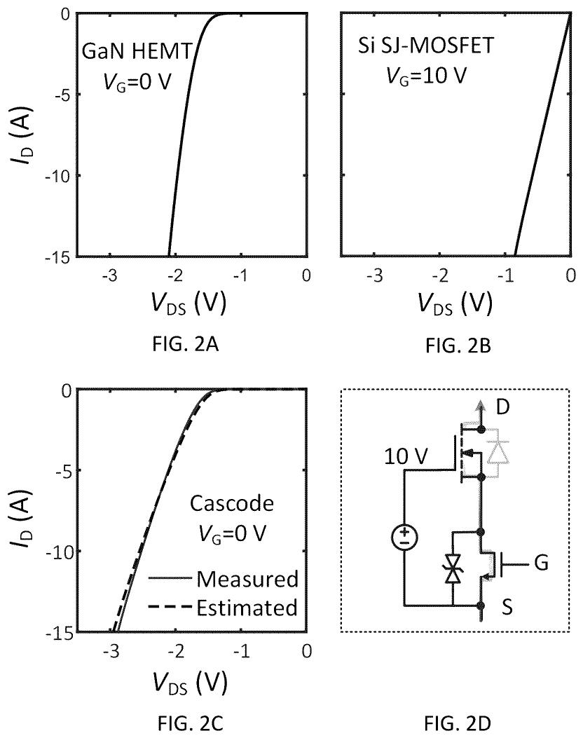

FIGS. 2A-2C show the reverse-conduction characteristics of the LV GaN HEMT, HV Si SJ-MOSFET, and the GaN/Si-SJ cascode device, respectively.

The reverse-conduction turn-on voltages of the LV GaN HEMT and the cascode device are almost identical. Moreover, the measured reverse-conduction characteristic of the cascode device is the same as the estimated result based on the assumption that all reverse-conduction current flows through the MOS channel, as shown in FIG. 2D. The results suggest that the reverse-conduction current in the cascode structure flows through the Si SJ-MOSFET mainly via the on-state MOS channel instead of the body diode. Such an operating mode during reverse conduction leads to a significant reduction of Qᵣᵣ and thus switching loss.

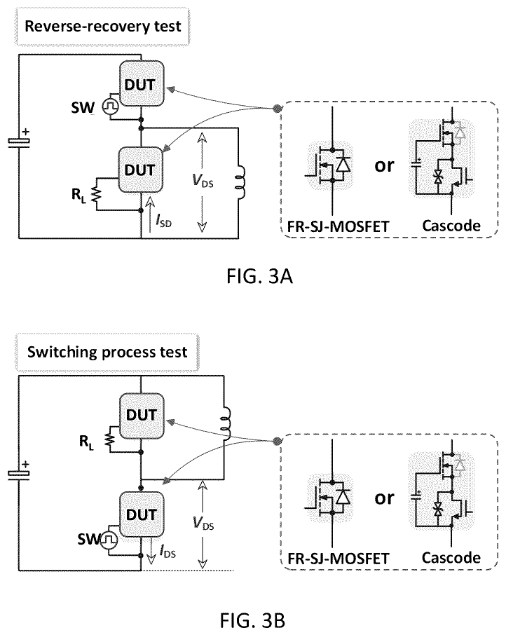

FIGS. 3A and 3B shows the test set-ups used to characterize the device's reverse-recovery performance and the switching performance, respectively. The device under test (DUT) can be a commercially available best-in-class fast-recovery (FR) SJ-MOSFET or the GaN/Si-SJ cascode device provided by the present invention. The reverse-recovery performance of the low-side DUT is evaluated with a half-bridge circuit featuring a low-side inductive load R_{L} and a high-side switching device SW, as shown in FIG. 3A. The effect of reverse recovery on switching loss is evaluated in the half-bridge circuit featuring a high-side inductive load R_{L} and low-side switching device SW, as shown in FIG. 3B.

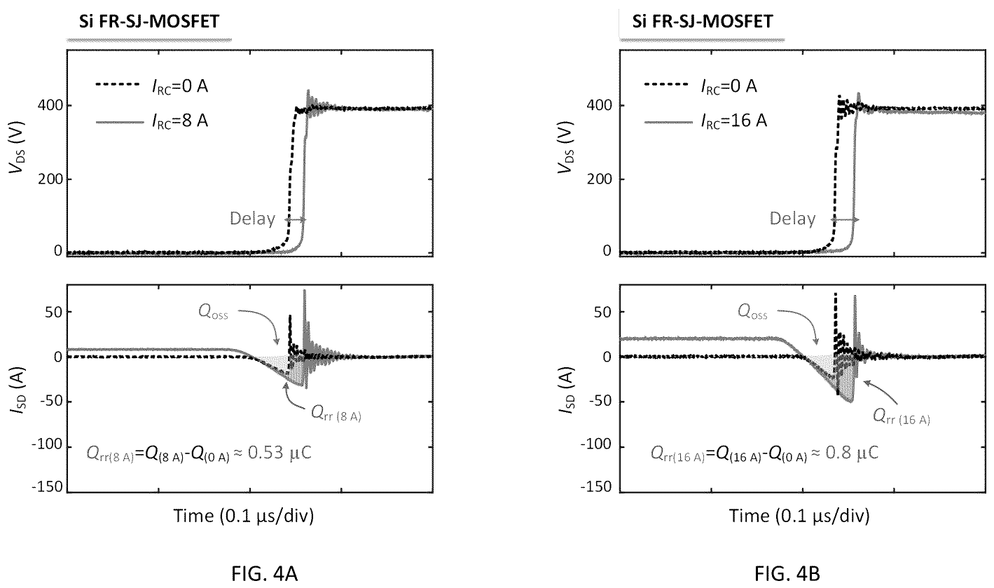

FIGS. 4A and 4B plot the voltage and current waveforms during the reverse-recovery process of the best-in-class Si FR-SJ-MOSFET at different reverse-conduction currents (I_{RC}). When the I_{RC} of DUTs is 0 A, the low-side DUT does not need to recover during the high-side turn-on process. Therefore, the current draining into the device is just the output-capacitance charging current of DUT, and integrating the current yields the output-capacitance charge (Qₒₛₛ) of DUT. At higher I_{RC} of 8 A and 20 A, the total charge draining into the device is increased significantly, which is attributed to the reverse recovery of the Si FR-SJ-MOSFET. Moreover, the delay at the V_{DS} rising edge also indicates the device needs additional time to recover the extra charge, i.e., Qᵣᵣ, before it can block high voltage.

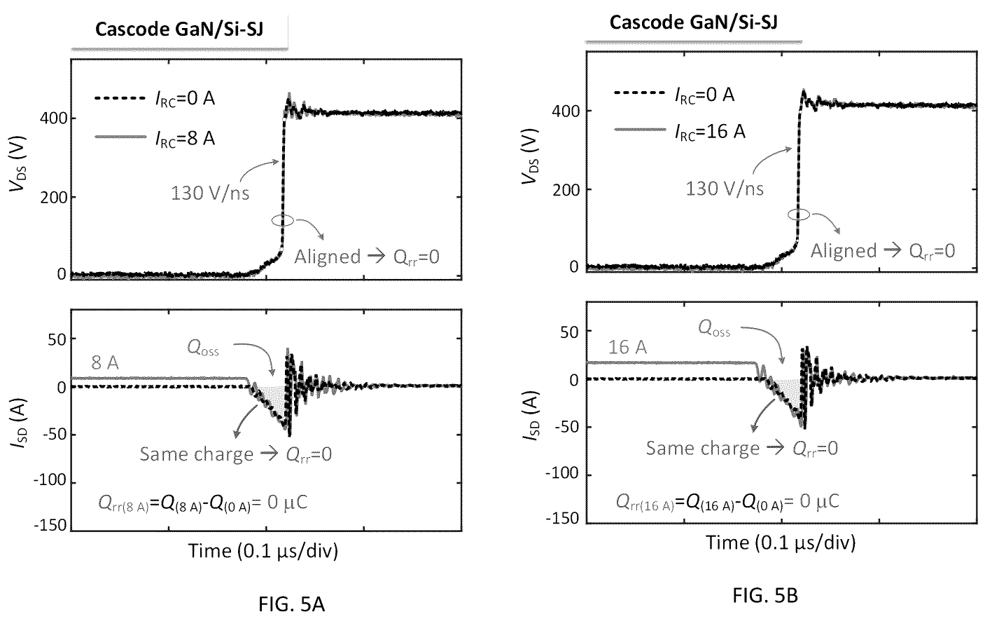

FIGS. 5A and 5B plot the voltage and current waveforms during the reverse-recovery process of the GaN/Si-SJ cascode device at different I_{RC}. Compared with the Si FR-SJ-MOSFET, when the I_{RC} of the GaN/Si-SJ cascode device is increased, the total charge drained into the device remains the same, suggesting the Qᵣᵣ of the cascode device is zero. Moreover, the perfect alignment of the DUT's drain-source voltage (VDs) waveforms at the rising edge also indicates the GaN/Si-SJ cascode device's Qᵣᵣ is zero, as the device does not need additional time to recover after reverse conduction.

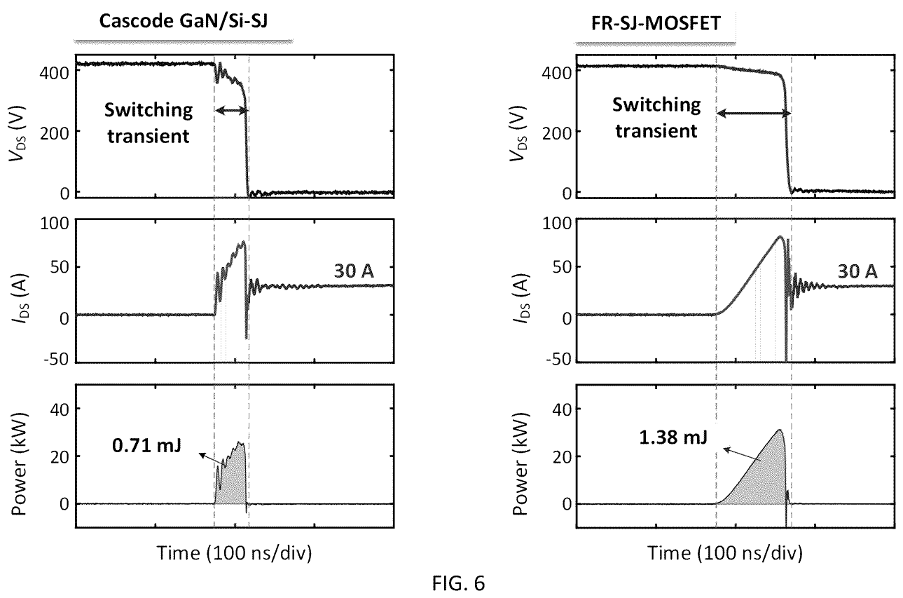

FIG. 6 plots the switching process of the GaN/Si-SJ cascode device and the FR-SJ-MOSFET. Compared with the Si FR-SJ-MOSFET, the switching transient of the GaN/Si-SJ cascode device is much shorter with much lower switching loss, which is the direct benefit of Qᵣᵣ suppression.

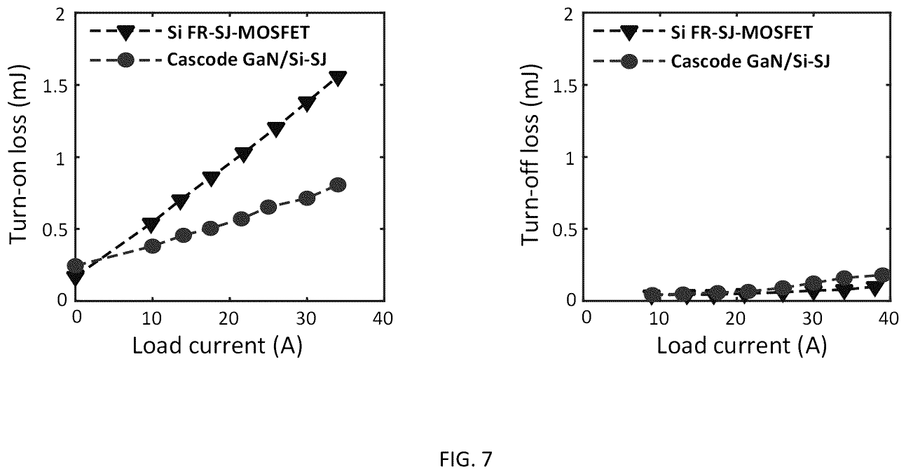

FIG. 7 compares the switching loss of the FR-SJ-MOSFET and the GaN/Si-SJ cascode device. Due to the Qᵣᵣ suppression, the switching loss of the cascode device is much lower than the best-in-class Si FR-SJ-MOSFET. Thanks to the absence of Qᵣᵣ in the GaN HEMT, the cascode structure can effectively suppress the reverse-recovery process SJ-MOSFET. The Qᵣᵣ of the 650-V/33-A Si SJ-MOSFET is decreased from 0.97 μC to only 0.02 μC at a reverse-conduction current of 30 A, leading to nearly 50% reduction in overall switching loss at high current levels.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

What is claimed is:

1. An electronic cascode power device having a high-side terminal, a low-side terminal and a control terminal, comprising:
a high-voltage silicon (Si) super-junction MOSFET with a drain connected to the high-side terminal of the cascode device;
a low-voltage gallium nitride (GaN) HEMT with a drain connected to a source of the high-voltage Si super-junction MOSFET, a source connected to the low-side terminal of the cascode device and a gate connected to the control terminal of the cascode device; and
an overvoltage clamping circuit connected between the drain and source of the low-voltage GaN HEMT.

2. The electronic cascode power device of claim 1, wherein
the low-voltage GaN HEMT contributes a first portion of an on-state resistance of the electronic cascode power device;
the high-voltage Si super-junction MOSFET contributes a second portion of the on-state resistance of the electronic cascode power device; and
the first portion is smaller than the second portion.

3. The electronic cascode power device of claim 1, wherein the Si bi-directional Zener diode is configured to prevent high voltage spikes on the low-voltage GaN HEMT.

4. The electronic cascode power device of claim 1, wherein
the high-voltage Si super-junction MOSFET is a normally-OFF MOSFET; and
the low-voltage GaN HEMT is a normally-OFF HEMT.

5. The electronic cascode power device of claim 4, further comprising a voltage source connected between the source of the low-voltage GaN HEMT and a gate of the high-voltage Si super-junction MOSFET.

6. The electronic cascode power device of claim 5, wherein the voltage source is a capacitor.

7. The electronic cascode power device of claim 1, wherein the high-voltage Si SJ-MOSFET is a normally-ON MOSFET; and the low-voltage GaN HEMT is a normally-OFF HEMT.

8. The electronic cascode power device of claim 1, wherein the overvoltage clamping circuit includes:
a first Zener diode having an anode connected to the drain of the low-voltage GaN HEMT; and
a second Zener diode having a cathode connected to a cathode of the first Zener diode and an anode connected to the source of the low-voltage GaN HEMT.

9. The electronic cascode power device of claim 1, wherein the overvoltage clamping circuit includes:
a pn diode having an anode connected to the drain of the low-voltage GaN HEMT; and
a Zener diode having a cathode connected to a cathode of the pn diode and an anode connected to the source of the low-voltage GaN HEMT.

10. The electronic cascode power device of claim 1, wherein the overvoltage clamping circuit includes: a Schottky barrier diode having an anode connected to the drain of the low-voltage GaN HEMT; and
a Zener diode having a cathode connected to a cathode of the Schottky barrier diode and an anode connected to the source of the low-voltage GaN HEMT.
